(19) United States
(12) Patent Application Publication
(10) Pub. No.: US 2018/0144997 A1
(43) Pub. Date: May 24, 2018

(54) SAMPLE WITH IMPROVED EFFECT OF BACKSIDE POSITIONING, FABRICATION METHOD AND ANALYSIS METHOD THEREOF

(71) Applicants: Qiang Chen, Shanghai (CN); Chinte Kuo, Shanghai (CN)

(72) Inventors: Qiang Chen, Shanghai (CN); Chinte Kuo, Shanghai (CN)

(21) Appl. No.: 15/390,521

(22) Filed: Dec. 25, 2016

(30) Foreign Application Priority Data
Nov. 22, 2016 (CN) 201611048175.5

(51) Int. Cl. H01L 21/66; H01L 21/304; G01B 11/14; G01R 31/28

(52) U.S. Cl. CPC H01L 22/20; H01L 22/12; G01R 31/2851; G01B 11/14; H01L 21/304

(57) ABSTRACT

A sample with improved effect of backside positioning, fabrication method and analysis method thereof are disclosed in the present invention. The present invention has formed the arc-shaped convex structure with a certain arc at the back surface of the substrate, so that the value of the numerical aperture of the conventional lens in the positioning analysis is increased. That is that using a conventional lens of the EMMI may also obtain a better positioning analysis result of the back side of the chip. In addition, depending on the different thicknesses of the substrate, convex structures with different arcs are formed. Therefore, only one lens is used to perform a positioning analysis for different samples, so as to greatly reduce the cost of analysis.

### CROSS-REFERENCE TO RELATED APPLICATION

This application claims the priority benefit of China patent application serial No. 201611048175.5, filed Nov. 22, 2016. The entire contents of the above-mentioned patent application are hereby incorporated by reference herein and made a part of the specifications.

### FIELD OF THE INVENTION

The present invention relates to the field of integrated circuit failure analysis technology, and particularly to a sample with improved effect of backside positioning, fabrication method and analysis method thereof.

### BACKGROUND OF THE INVENTION

EMMI (emission microscope multilevel inspection) is a positioning tool for failure analysis widely used that can be used for positioning analysis of various defects, such as leakage of chip junctions, ESD damage, gate oxide breakdown, and abnormal doping.

With the increasing of metal layers up to ten or more in the back-end process of integrated circuits manufacturing, due to the blocking of the metal layers, it is difficult to find defects produced in the front-end process of integrated circuits manufacturing by adopting a method of failure positioning from the front side of the chip. Therefore, a method of failure positioning from the back side of the chip has been widely used.

With the continuous development of process nodes, device size to be analyzed is becoming smaller and smaller. So, it is necessary to improve the optical resolution of image in order to obtain a sufficiently clear analysis result in a failure positioning analysis.

The optical resolution satisfies the following formula:

r=0.61λ/NA

In which, the r is the resolution; the λ is the wavelength of light; and the NA is the numerical aperture.

It can be seen from the above formula that the resolution can be improved by reducing the wavelength of light and increasing the numerical aperture. However, in the EMMI failure analysis, only light having a wavelength greater than lum can pass through silicon substrate, the resolution of the EMMI analysis can only be improved by increasing the numerical aperture.

Now commercially available products, such as FEI's SIL (Solid Immersion Lens), can effectively improve the numerical aperture, thereby enhancing the EMMI analysis resolution.

Referring to FIG. 1 and FIG. 2, which are schematic views for sample analysis using a conventional lens and a SIL lens, respectively. Shown from the FIG. 1, part of the light will be refracted at the silicon-air interface of the sample when a conventional lens is used. However, all of the light will be almost reflected back to the lens when a SIL lens is used shown in the FIG. 2. The value of the numerical aperture is greatly increased to about 2.4 from about 0.85 of the conventional lens. Therefore, the SIL performance is improved nearly 3 times. Meantime, the receiving efficiency of the photon is increased to about 10% from about 1.5% of the conventional lens.

However, the price of the SIL lens is very expensive, up to tens of thousands of dollars. Depending on the different thicknesses of the silicon substrate, a number of SIL lenses with different types are required. Therefore, the problem of high analysis cost is caused.

### BRIEF SUMMARY OF THE DISCLOSURE

To overcome the problems as mentioned above, it is an object of the present invention to provide a method and a sample for improving the positioning effect of backside EMMI, and a sample fabrication method.

To achieve above object, technical solutions of the present invention are as follows:

A sample for improving the positioning effect of backside EMMI is disclosed in the present invention, which comprising: a substrate containing one or more semiconductor devices, and one or more arc-shaped convex structures; the position of the arc-shaped convex structure corresponds to the area to be analyzed below it.

A sample fabrication method for improving the positioning effect of backside EMMI according to the above mentioned sample is also disclosed, which comprising the steps of:

Step S01: providing a chip to be analyzed, wherein the chip comprises a substrate containing one or more semiconductor devices;

Step S02: exposing at least the back surface of the substrate corresponding to the area to be analyzed, and performing a thinning process;

Step S03: forming an arc-shaped convex structure having a certain arc at the exposed back surface of the substrate according to the size of the area to be analyzed, and completing the sample fabrication.

A method for improving the positioning effect of backside EMMI is also disclosed, which comprising: providing a sample fabricated by a sample fabrication method for improving the positioning effect of backside EMMI according to any one of claims 7-11; using a conventional lens to perform a positioning analysis for the area to be analyzed corresponding to the arc-shaped convex structure.

Concluded from the above solutions that, the present invention has used an existing ion beam equipment form the arc-shaped convex structure with a certain arc at the back surface of the substrate, so that the value of the numerical aperture of the conventional lens in the positioning analysis is increased. That is that using a conventional lens of the EMMI may also obtain a better positioning analysis result of the back side of the chip. In addition, depending on the different thicknesses of the substrate, convex structures with different arcs are formed. Therefore, only one lens is used to perform a positioning analysis for different samples, so as to greatly reduce the cost of analysis.

### BRIEF DESCRIPTION OF THE DRAWINGS

FIGS. 1-2 are schematic views for sample analysis using a conventional lens and a SIL lens, respectively;

FIG. 3 is a schematic view of a sample for improving the positioning effect of backside EMMI according to a preferred embodiment of the present invention;

FIGS. 4-5 are schematic views illustrating a fabrication step of a sample for improving the positioning effect of backside EMMI according to a preferred embodiment of the present invention;

FIG. 6 is a schematic view illustrating a positioning analysis for a sample fabricated basing the method described in the FIGS. 4-5 according to a preferred embodiment of the present invention.

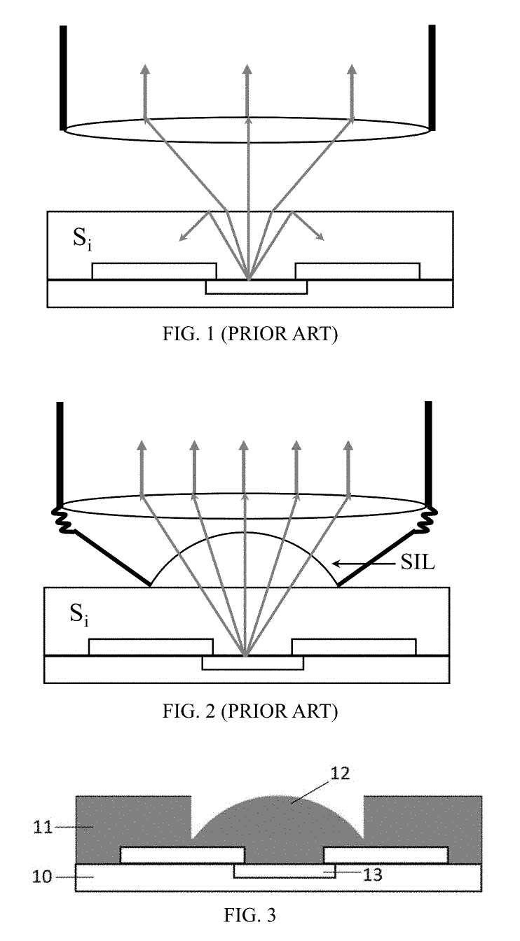

### DETAILED DESCRIPTION OF THE EMBODIMENTS

The present invention will be described in further details hereinafter by referring to the accompanying drawings, so as to provide a better understanding of the present invention.

It should be noted that, in the following specific embodiments, when these embodiments of the present invention are described in detail, in order to clearly illustrate the structure of the present invention to facilitate explanation, the accompanying drawings are not necessarily drawn to scale, some features in the drawings may have been fragmentary enlarged, deformed or simplified. Therefore, it should be avoided to understand this as a limitation to the present invention.

Referring to FIG. 3, which is a schematic view of a sample for improving the positioning effect of backside EMMI according to a preferred embodiment of the present invention. As shown in the FIG. 3, the present invention provides a sample for improving the positioning effect of backside EMMI, which comprising a substrate 11, such as a silicon substrate 11 or other suitable substrates, containing one or more semiconductor devices, such as a gate 13 and a multilayers metal layer 10 on top surface of the substrate (the shown substrate in the FIG. 3 is facing down).

Referring to FIG. 3, again. There is at least one arc-shaped convex structure 12 on back surface of the substrate 11. The position of the arc-shaped convex structure 12 corresponds to the area to be analyzed below it, i.e., the gate 13. If the sample has a plurality of areas to be analyzed, a corresponding number of arc-shaped convex structures may be provided on the back surface of the substrate. The rest of the back surface, except the arc-shaped convex structure, has no corresponding relation (higher, lower or equal, all are suitable) to the highest point of the arc-shaped convex structure.

The size and the arc of the arc-shaped convex structure 12 is decided by the used lens of the EMMI. The arc-shaped convex structure covers the area to be analyzed below it. The arc-shaped convex structure 12 may have a smooth surface to improve the transmission and reflectivity of the light and enhance the positioning effect. Preferably, the arc-shaped convex structure has a spherical surface.

In order to enhance the light transmission, the back surface of the substrate 11 may be thinned and planarized to form a sample having a suitable thickness and a smooth surface.

The arc-shaped convex structure with a certain arc formed on the back surface of the substrate may be equivalent to the improvement of the numerical aperture of the conventional lens. That is that using a conventional lens of the EMMI may also obtain a better positioning analysis result of the back side of the chip.

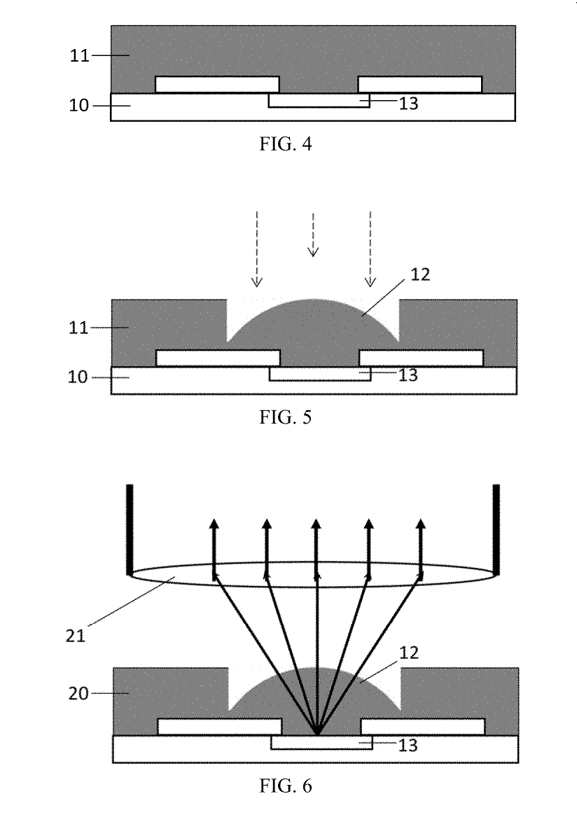

A sample fabrication method basing on the above mentioned sample is also disclosed in the present invention. Referring to FIGS. 4-5, which are schematic views illustrating a fabrication step of a sample for improving the positioning effect of backside EMMI according to a preferred embodiment of the present invention. As shown in the FIGS. 4-5, a sample fabrication method for improving the positioning effect of backside EMMI according to any one of claims 1 to 6, comprising the steps of:

Step S01: providing a chip to be analyzed, wherein the chip comprises a substrate containing one or more semiconductor devices.

Referring to FIG. 4. The chip comprises a substrate 11, such as a silicon substrate 11 or other suitable substrates. One or more semiconductor devices, such as a gate 13 and a multilayers metal layer 10, are manufactured on top surface of the substrate.

Step S02: exposing at least the back surface of the substrate corresponding to the area to be analyzed, and performing a thinning process.

Referring to FIG. 4, again. The gate 13 shown in the FIG. 4 is an area to be analyzed. At least the area of the back surface of the substrate 11 corresponding to the gate 13 is exposed out. If the area mentioned above is covered by other structures, a processing step should be proceeded to remove them. A polishing method (i.e., CMP) is used to thin and planarize the back surface of the substrate to obtain a sample substrate 11 having a suitable thickness and a smooth surface.

Step S03: forming an arc-shaped convex structure having a certain arc at the exposed back surface of the substrate according to the size of the area to be analyzed, and completing the sample fabrication.

Referring to FIG. 5. The arc-shaped convex structure 12 having a required arc at the exposed back surface of the substrate is formed by utilizing a focused ion beam method in the existing ion beam equipment. If the sample has a plurality of areas to be analyzed, a corresponding number of arc-shaped convex structures may be provided on the back surface of the substrate. The rest of the back surface, except the arc-shaped convex structure, may be manufactured in the form of higher than, lower than or equal to the highest point of the arc-shaped convex structure.

The arc-shaped convex structure 12 is positioned corresponding to the area to be analyzed below it, i.e., the gate 13, and covers the area to be analyzed below it. Therefore, the area to be analyzed needs to be positioned in advance according to its size. An ion beam or a laser is used to positioning the area to be analyzed.

During the process of manufacturing the arc-shaped convex structure 12, the desired arc may be manufactured by controlling the ion beam with a scrip program. Therefore, only one lens is used to perform a positioning analysis for different samples, so as to greatly reduce the cost of analysis.

A method for improving the positioning effect of backside EMMI is also disclosed in the present invention. Referring to FIG. 6, which is a schematic view illustrating a positioning analysis for a sample fabricated basing the method described in the FIGS. 4-5 according to a preferred embodiment of the present invention. As shown in the FIG. 6, a method for improving the positioning effect of backside EMMI, comprising: providing a sample 20 fabricated by a sample fabrication method for improving the positioning effect of backside EMMI mentioned above; using a conventional lens 21 to perform a positioning analysis for the area to be analyzed (i.e., the gate 13) corresponding to the arc-shaped convex structure 12.

In summary, the present invention has formed the arc-shaped convex structure 12 with a certain arc at the back surface of the substrate 20, so that the value of the numerical aperture of the conventional lens in the positioning analysis is increased. That is that using a conventional lens of the EMMI may also obtain a better positioning analysis result of the back side of the chip. In addition, depending on the different thicknesses of the substrate, convex structures with different arcs, areas and height are formed in advance. Therefore, only one lens is used to perform a positioning analysis for different samples, so as to greatly reduce the cost of analysis.

Although the present invention has been disclosed as above with respect to the preferred embodiments, they should not be construed as limitations to the present invention. Various modifications and variations can be made by the ordinary skilled in the art without departing the spirit and scope of the present invention. Therefore, the protection scope of the present invention should be defined by the appended claims.

1. A sample with improved effect of backside positioning, comprising: a substrate containing one or more semiconductor devices, and one or more arc-shaped convex structures; the position of the arc-shaped convex structure corresponds to the area to be analyzed below it.

2. The sample according to claim 1, wherein the material of the substrate is silicon; before forming the arc-shaped convex structure, the back surface of the substrate is planarized.

3. The sample according to claim 1, wherein the arc-shaped convex structure has a smooth surface.

4. The sample according to claim 1, wherein the arc-shaped convex structure has a spherical surface and covers the area to be analyzed below it.

5. The sample according to claim 2, wherein the arc-shaped convex structure has a spherical surface and covers the area to be analyzed below it.

6. The sample according to claim 3, wherein the arc-shaped convex structure has a spherical surface and covers the area to be analyzed below it.

7. A sample fabrication method for improving the positioning effect of backside EMMI according to claim 1, comprising the steps of:
Step S01: providing a chip to be analyzed, wherein the chip comprises a substrate containing one or more semiconductor devices;
Step S02: exposing at least the back surface of the substrate corresponding to the area to be analyzed, and performing a thinning process;
Step S03: forming an arc-shaped convex structure having a certain arc at the exposed back surface of the substrate according to the size of the area to be analyzed, and completing the sample fabrication.

8. The sample fabrication method according to claim 7, wherein, in the Step S01, the material of the substrate is silicon; in the Step S02, a polishing method is used to thin and planarize the back surface of the substrate.

9. The sample fabrication method according to claim 7, wherein, in the Step S03, a focused ion beam method is used to form the arc-shaped convex structure having a required arc at the exposed back surface of the substrate.

10. The sample fabrication method according to claim 7, wherein, in the Step S03, positioning for the area to be analyzed is performed firstly.

11. The sample fabrication method according to claim 10, wherein, in the Step S03, an ion beam or a laser is used to positioning the area to be analyzed.

12. A analysis method for improving the positioning effect of backside EMMI, comprising: providing a sample fabricated by a sample fabrication method for improving the positioning effect of backside EMMI according to claim 7; using a conventional lens to perform a positioning analysis for the area to be analyzed corresponding to the arc-shaped convex structure.

13. A analysis method for improving the positioning effect of backside EMMI, comprising: providing a sample fabricated by a sample fabrication method for improving the positioning effect of backside EMMI according to claim 8; using a conventional lens to perform a positioning analysis for the area to be analyzed corresponding to the arc-shaped convex structure.

14. A analysis method for improving the positioning effect of backside EMMI, comprising: providing a sample fabricated by a sample fabrication method for improving the positioning effect of backside EMMI according to claim 9; using a conventional lens to perform a positioning analysis for the area to be analyzed corresponding to the arc-shaped convex structure.

15. A analysis method for improving the positioning effect of backside EMMI, comprising: providing a sample fabricated by a sample fabrication method for improving the positioning effect of backside EMMI according to claim 10; using a conventional lens to perform a positioning analysis for the area to be analyzed corresponding to the arc-shaped convex structure.

16. A analysis method for improving the positioning effect of backside EMMI, comprising: providing a sample fabricated by a sample fabrication method for improving the positioning effect of backside EMMI according to claim 11; using a conventional lens to perform a positioning analysis for the area to be analyzed corresponding to the arc-shaped convex structure.
